(19) United States
(12) Patent Application Publication
(10) Pub. No.: US 2026/0165072 A1
(43) Pub. Date: Jun. 11, 2026

(54) HEAT TREATMENT APPARATUS FOR HEATING WAFERS

(71) Applicant: SAMSUNG ELECTRONICS CO., LTD., Suwon-si (KR)

(72) Inventors: Hyoju AN, Suwon-si (KR); Dongyul KIM, Siheung-si (KR); Seungmin BAEK, Suwon-si (KR); Kitae PARK, Suwon-si (KR)

(73) Assignees: SAMSUNG ELECTRONICS CO., LTD., Suwon-si (KR); Lambda Micro Co., Ltd, Siheung-si (KR)

(21) Appl. No.: 19/384,623

(22) Filed: Nov. 10, 2025

(30) Foreign Application Priority Data
Dec. 6, 2024 (KR) 10-2024-0180594

(51) Int. Cl. H01L 21/67; H01L 21/673

(52) U.S. Cl. CPC H10P 72/0434; H10P 72/0436; H10P 72/0602; H10P 72/127

(57) ABSTRACT

A heat treatment apparatus includes a wafer boat accommodating a plurality of wafers, a reaction tube surrounding the wafer boat and defining a sealed first internal space, a chamber surrounding the reaction tube and having a first side portion and a second side portion facing each other, and a multi-heating device including a first heating device and a second heating device configured to heat the plurality of wafers. The first heating device includes a gas supply device configured to supply a heat transfer gas to the first internal space and a gas heating device configured to heat the heat transfer gas. The second heating device includes a first microwave source configured to generate a first microwave having a first variable frequency and a first microwave transmission portion and configured to transmit the first microwave.

### CROSS-REFERENCE TO RELATED APPLICATION

This application claims priority under 35 U.S.C. § 119 to Korean Patent Application No. 10-2024-0180594, filed on Dec. 6, 2024 in the Korean Intellectual Property Office (KIPO), the contents of which are herein incorporated by reference in their entirety.

### BACKGROUND

### 1. Field

Example embodiments relate to a heat treatment apparatus. More particularly, example embodiments relate to a heat treatment apparatus having a variable frequency microwave VFM irradiation device for heating wafers.

### 2. Description of the Related Art

In a heat treatment process such as a curing process, a heating device may be mainly used to heat wafers using gases such as nitrogen (N₂). However, since the heating device may cause a temperature difference between a central region and a peripheral region of the wafer, the heating device may have limitations in increasing a heating rate (temperature increase rate) while performing a heat treatment process uniformly over the entire surface of the wafer. Accordingly, the heating device that heat wafers using gases may have a problem that a process time is relatively long.

### SUMMARY

Example embodiments provide a heat treatment apparatus having a heating device capable of performing a heat treatment process uniformly over the entire surface of a wafer with a fast heating rate.

In accordance with example embodiments, a heat treatment apparatus includes a wafer boat accommodating a plurality of wafers, a reaction tube surrounding the wafer boat and defining a sealed first internal space, a chamber surrounding the reaction tube and having a first side portion and a second side portion facing each other, and a multi-heating device including a first heating device and a second heating device configured to heat the plurality of wafers. The first heating device includes a gas supply device configured to supply a heat transfer gas to the first internal space and a gas heating device configured to heat the heat transfer gas. The second heating device includes a first microwave source configured to generate a first microwave having a first variable frequency that varies within a first frequency range and a first microwave transmission portion including at least one first wave guide that penetrates the first side portion of the chamber and configured to transmit the first microwave.

In accordance with example embodiments, a heat treatment apparatus includes a wafer boat having receiving grooves for receiving a plurality of wafers, respectively, a reaction tube surrounding the wafer boat and defining a sealed first internal space, a chamber surrounding the reaction tube and having a first side portion and a second side portion facing each other, a first heating device configured to heat the plurality of wafers, the first heating device including a gas supply device configured to supply a heat transfer gas to the first internal space and a gas heating device configured to heating the heat transfer gas, and a second heating device including a first microwave source configured to generate a first microwave having a first variable frequency that varies within a first frequency range, a first microwave transmission portion having at least one first wave guide that penetrates the first side portion of the chamber and transmits the first microwave, a second microwave source configured to generate a second microwave having a second variable frequency that varies within a second frequency range, and a second microwave transmission portion having at least one second wave guide that penetrates the second side portion of the chamber and configured to transmit the second microwave.

In accordance with example embodiments, a heat treatment apparatus includes a wafer boat having receiving grooves for receiving a plurality of wafers, a reaction tube surrounding the wafer boat and defining a sealed first internal space, a chamber surrounding the reaction tube and having a first side portion and a second side portion facing each other, a first heating device configured to heat the plurality of wafers, the first heating device including a gas supply device having at least one gas supply pipe in fluid communication with the first internal space and configured to supply a heat transfer gas to the first internal space, an external heating device disposed between the first internal space and the gas supply device and configured to heat the heat transfer gas, and at least one heater disposed in the first side portion and the second side portion of the chamber to surround the plurality of wafers and configured to heat the chamber, and a second heating device including a first microwave source configured to generate a first microwave having a first variable frequency that varies within a first frequency range and a first microwave transmission portion having at least one first wave guide that penetrates the first side portion of the chamber and configured to transmit the first microwave.

In accordance with example embodiments, a heat treatment apparatus may include a wafer boat for accommodating a plurality of wafers, a reaction tube surrounding the wafer boat and defining a first internal space, a chamber surrounding the reaction tube and having first and second side portions facing each other, and a multi-heating device including a first heating device and a second heating device that are configured to heat the plurality of wafers.

The first heating device may include a gas supply device for supplying a heat transfer gas to the first internal space and a gas heating device for heating the heat transfer gas, and the second heating device may include a first microwave source for generating a first microwave having a first variable frequency that varies within a first frequency range and a first microwave transmission portion having at least one first waveguide that penetrates one of the first and second side portions of the chamber and configured to transmit the first microwave.

Accordingly, the multi-heating device may perform a heat treatment process uniformly over the entire surface of the wafer while having a fast heating rate. Thus, a process time consumed in a heat treatment process such as a curing process may be reduced, thereby increasing the efficiency of the process.

### BRIEF DESCRIPTION OF THE DRAWINGS

Example embodiments will be more clearly understood from the following detailed description taken in conjunction with the accompanying drawings. FIGS. 1 to 9 represent non-limiting, example embodiments as described herein.

FIG. 1 is a cross-sectional view illustrating a heat treatment apparatus in accordance with example embodiments.

FIG. 2 is a cross-sectional view illustrating a heat treatment apparatus in accordance with example embodiments.

FIG. 3 is a cross-sectional view illustrating a heat treatment apparatus in accordance with example embodiments.

FIG. 4 is a cross-sectional view illustrating a heat treatment apparatus in accordance with example embodiments.

FIG. 5 is a cross-sectional view illustrating a heat treatment apparatus in accordance with example embodiments.

FIG. 6 is a cross-sectional view illustrating a heat treatment apparatus in accordance with example embodiments.

FIG. 7 is a cross-sectional view illustrating a heat treatment apparatus in accordance with example embodiments.

FIG. 8 is a cross-sectional view illustrating a heat treatment apparatus in accordance with example embodiments.

FIG. 9 is a cross-sectional view illustrating a heat treatment apparatus in accordance with example embodiments.

### DETAILED DESCRIPTION OF EXAMPLE EMBODIMENTS

Hereinafter, example embodiments will be explained in detail with reference to the accompanying drawings.

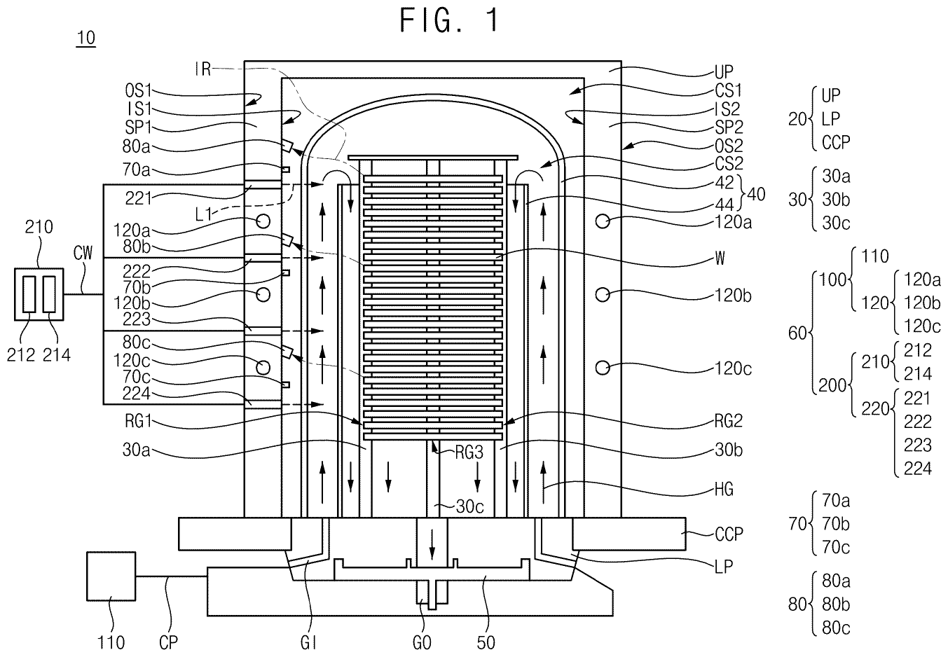

FIG. 1 is a cross-sectional view illustrating a heat treatment apparatus in accordance with example embodiments.

Referring to FIG. 1, a heat treatment apparatus 10 may include a chamber 20 defining a first internal space CS1, a wafer boat 30 disposed within the first internal space CS1 of the chamber 20 and accommodating a plurality of wafers W, a plurality of tubes 40 surrounding the wafer boat 30 and defining a second internal space CS2, a wafer lifting device 50 configured to load the plurality of wafers W on the wafer boat 30, and a multi-heating device 60 including a first heating device 100 and a second heating device 200 for heating the plurality of wafers W. Additionally, the heat treatment apparatus 10 may further include a plurality of temperature sensors 70 for measuring temperature of the first internal space CS1 and a plurality of infrared temperature sensors 80 for measuring temperature of at least one wafer of the plurality of wafers W.

For example, the heat treatment apparatus may include a curing device for heating and curing a material on a wafer (or substrate). For example, the wafer may include a plurality of insulating layers and a plurality of metal patterns provided in the plurality of insulating layers to be at least partially exposed from the plurality of insulating layers. The heat treatment apparatus may be an apparatus that is configured to heat and cure an insulating material on which a photolithography process has been performed, to form an insulating pattern for forming the plurality of metal patterns.

In example embodiments, the chamber 20 may define the first internal space CS1, and may include an upper chamber UP, a lower chamber LP, and a connection CCP connecting the upper chamber UP and the lower chamber LP. For example, the first internal space may be a process space in which a process is performed.

The upper chamber UP of the chamber 20 may include a first side portion SP1 having a first outer surface OS1 and a first inner surface IS1 opposite to the first outer surface, and a second side portion SP2 having a second outer surface OS2 and a second inner surface IS2 opposite to the second outer surface. For example, the first inner surface IS1 and the second inner surface IS2 may be inner surfaces of the chamber defining the first inner space CS1.

In example embodiments, the wafer boat 30 may be disposed in the first inner space CS1 of the chamber 20 and may include a plurality of supports 30a, 30b, 30c each having a plurality of receiving grooves. For example, the wafer boat may be a structure for fixedly support a plurality of wafers that are inserted into the plurality of receiving grooves.

For example, the wafer boat 30 may include a first support 30a, a second support 30b, and a third support 30c that are spaced apart from each other in a horizontal direction. The first support 30a may include a plurality of first receiving grooves RG1 that are spaced apart from each other in a vertical direction, the second support 30b may include a plurality of second receiving grooves RG2 that are spaced apart from each other in the vertical direction, and the third support 30c may include a plurality of third receiving grooves RG3 that are spaced apart from each other in the vertical direction. The vertical direction may refer to a direction in which the plurality of wafers W are stacked in the chamber 20 and may intersect the horizontal direction.

The wafer boat 30 may include a heat-resistant material that is capable of withstanding heat during a heat treatment process. For example, the heat treatment process may include a curing process. In addition, the wafer boat 30 may include a transparent material to transmit light. For example, the wafer boat may include quartz.

In example embodiments, the plurality of tubes 40 may include a reaction tube 42 disposed in the first internal space CS1 and having a second internal space CS2, and an inner tube 44 disposed in the second internal space CS2 to surround the wafer boat 30. For example, the second internal space may be a reaction space where a heat transfer gas is introduced to meet the plurality of wafers, as will be described later. The reaction tube may be a structure for defining the sealed reaction space. The inner tube may be a structure for controlling a flow path of the heat transfer gas so that the heat transfer gas can evenly meet the plurality of wafers W accommodated in the wafer boat 30.

The reaction tube 42 and the inner tube 44 may include a heat-resistant material that is capable of withstanding heat during the curing process. In addition, the reaction tube 42 and the inner tube 44 may include a transparent material for transmitting light. For example, the reaction tube and the inner tube may include quartz.

In example embodiments, the wafer lifting device 50 for wafers may move in the vertical and horizontal directions and insert the plurality of wafers W into the plurality of receiving grooves RG1, RG2, RG3 of the wafer boat 30.

In example embodiments, the multi-heating device 60 may include a first heating device 100 that includes a gas supply device 110 configured to deliver a heat transfer gas HG to the second internal space CS2 of the reaction tube 42 and a plurality of heaters 120 configured to heat the heat transfer gas HG supplied by the gas supply device 110. In addition, the multi-heating device 60 may include a second heating device 200 that includes a first microwave source 210 configured to generate a first microwave L1 for heating the plurality of wafers W and a first microwave transmission portion 220 provided to penetrate the first side portion SP1 of the chamber 20 and configured to transmit the first microwave L1 to the plurality of wafers W. For example, the second heating device 200 may be a variable frequency microwave VFM device for irradiating a microwave whose frequency changes within a certain range.

In example embodiments, the first heating device 100 may include the gas supply device 110 that includes at least one gas supply pipe GI, at least one gas discharge pipe GO, and connecting pipes CP, and the plurality of heaters 120 having first to third heaters 120a, 120b, 120c that are disposed in the first side portion SP1 and the second side portion SP2 of the chamber 20 and are spaced apart from each other.

The at least one gas supply pipe GI may be disposed in the lower chamber LP and may be in fluid communication with the second internal space CS2 of the reaction tube 42. For example, the at least one gas supply pipe GI may be an inlet pipe for delivering the heat transfer gas HG to the second internal space CS2. In addition, the at least one gas discharge pipe GO may be disposed in the lower chamber LP and may be in fluid communication with the second internal space CS2 of the reaction tube 42. For example, the at least one gas discharge pipe GO may be an outlet pipe for delivering the heat transfer gas HG from the second internal space CS2 to the outside. The connecting pipes CP may be disposed between the at least one gas supply pipe GI and the gas supply device 110, and may be a plurality of pipes each in fluid communication with the at least one gas supply pipe GI and the gas supply device 110.

For example, the heat transfer gas may include nitrogen (N₂) gas or argon (Ar) gas. However, example embodiments are not limited thereto, and the type of the heat transfer gas may be varied.

The first to third heaters 120a, 120b, 120c may be disposed in the first side portion SP1 and the second side portion SP2 of the chamber 20 to surround the plurality of wafers W. In addition, the first to third heaters 120a, 120b, 120c may be arranged to be spaced apart from each other in the vertical direction. For example, the first to third heaters 120a, 120b, 120c may be elements for heating the chamber 20 to heat the heat transfer gas HG disposed within the reaction tube 42. In addition, the first to third heaters 120a, 120b, 120c may be elements for heating the chamber 20 to reduce a temperature difference between the first outer surface OS1 and the first inner surface IS1 of the chamber 20 or between the second outer surface OS2 and the second inner surface IS2 of the chamber 20. For example, the first to third heaters 120a, 120b, 120c may include a resistance heating element that emits heat generated when current flows by using electrical resistance.

For example, the heat transfer gas HG may be injected into the second internal space CS2 of the reaction tube 42 through the gas supply device 110, the connecting pipes CP, and the at least one gas supply pipe GI. Then, the injected heat transfer gas HG may move between the reaction tube 42 and the inner tube 44, and then, the injected heat transfer gas HG may move toward the at least one gas discharge pipe GO through the inside of the inner tube 44. At this time, the heat transfer gas HG may be heated by the first to third heaters 120a, 120b, 120c while passing between the reaction tube 42 and the inner tube 44 or while moving inside the inner tube 44. And, the heated heat transfer gas HG may heat the plurality of wafers W while moving inside the inner tube 44. Then, the heat transfer gas HG may be discharged to the outside through the at least one gas discharge pipe GO.

In example embodiments, the second heating device 200 may include the first microwave source 210 that includes a first microwave controller 212 and a first microwave amplifier 214 and the first microwave transmission portion 220 that includes a plurality of first wave guides 221, 222, 223, 224.

For example, the first microwave controller 212 may be a portion for generating the first microwave L1 having a first variable frequency W1 that varies within a preset first frequency range. In addition, the first microwave amplifier may be a portion for amplifying the first microwave L1. For example, the first variable frequency W1 may be within a range (C band) of 4 GHz to 8 GHz. For example, the first variable frequency W1 may be within a range of 5.8 GHz to 6.8 GHz. However, example embodiments are not limited thereto, and the frequency range of the first variable frequency W1 may be changed.

The plurality of first wave guides 221, 222, 223, 224 may penetrate the first side portion SP1 to extend from the first outer surface OS1 of the first side portion SP1 of the chamber 20 to the first inner surface IS1. For example, the plurality of first wave guides 221, 222, 223, 224 may include first to fourth guides 221, 222, 223, 224 that are spaced apart from each other in the vertical direction. Each of the first to fourth wave guides 221, 222, 223, 224 may be connected to the first microwave source 210 through connecting guides CW that are disposed between the first to fourth guides 221, 222, 223, 224 and the first microwave source 210.

Although several wave guides are illustrated in the figure, it will be appreciated that example embodiments are not limited thereto. Accordingly, the number and arrangement of wave guides may vary.

For example, the first microwave L1 generated from the first microwave controller 212 may be amplified while passing through the first microwave amplifier 214. Then, the amplified first microwave L1 may be irradiated into the first internal space CS1 as the process space through the connection guides CW and the plurality of first wave guides 221, 222, 223, 224. Then, the first microwave L1 may pass through the reaction tube 42 and the inner tube 44 and reach the plurality of wafers W to heat the plurality of wafers W.

Accordingly, the multi-heating device 60 may effectively heat the plurality of wafers W by using the first heating device and the second heating device. For example, the multi-heating device 60 may heat the plurality of wafers W through convective heat transfer and conductive heat transfer by the heat transfer gas HG supplied and heated by the first heating device 100. In addition, the multi-heating device 60 may uniformly heat the plurality of wafers W overall by using electromagnetic waves by the first microwave L1 irradiated by the second heating device 200. For example, the first heating device 100 may heat each of the plurality of wafers W from the outside toward the inside, and the second heating device 200 may uniformly heat each of the plurality of wafers W. Thus, the multi-heating device 60 may perform a heat treatment process uniformly over the entire surface of the wafer while having a fast heating rate.

In example embodiments, the plurality of temperature sensors 70 may be spaced apart from each other in the vertical direction and may be disposed in the first side portion SP1 of the chamber 20. For example, the plurality of temperature sensors 70 may include first to third temperature sensors 70a, 70b, 70c for measuring the temperature of the first internal space CS1 as the process space.

In example embodiments, the plurality of infrared temperature sensors 80 may be spaced apart from each other in the vertical direction and may be disposed in the first side portion SP1 of the chamber 20. For example, the plurality of infrared temperature sensors 80 may include first to third infrared temperature sensors 80a, 80b, 80c for measuring the temperature of each of the plurality of wafers W. For example, the infrared temperature sensor may be a device that directly measures the temperature of an individual wafer by measuring infrared radiation energy generated from the wafer.

Although several temperature sensors and infrared temperature sensors are illustrated in the figure, it will be appreciated that example embodiments are not limited thereto. Accordingly, the number and arrangement of the temperature sensors and the infrared temperature sensors may vary.

As mentioned above, the heat treatment apparatus 10 may include the chamber 20 defining the first internal space CS1 as the process space, the wafer boat 30 disposed within the first internal space CS1 and accommodating the plurality of wafers W, the plurality of tubes 40 including the reaction tube 42 disposed in the first internal space CS1 and configured to define the second internal space CS2 as a reaction space and the inner tube 44 disposed in the second internal space CS2 to surround the wafer boat 30, the wafer lifting device 50 configured to insert the plurality of wafers W into the plurality of receiving grooves RG1, RG2, RG3 of the wafer boat 30, and the multi-heating device 60 including the first heating device 100 and the second heating device 200 for heating the plurality of wafers W.

The first heating device 100 may include a gas heating device including the gas supply device 110 for supplying the heat transfer gas HG to the second internal space CS2 and the plurality of heaters 120 for heating the heat transfer gas HG, and the second heating device 200 may include the first microwave source 210 for generating the first microwave L1 having the first variable frequency W1 that varies within a first range and the first microwave transmission portion 220 having the plurality of first wave guides 221, 222, 223, 224 that penetrate the first side portion SP1 of the chamber 20 to transmit the first microwave L1.

Accordingly, the multi-heating device 60 may perform a heat treatment process uniformly over the entire surface of the wafer while having a fast heating rate. Thus, a process time consumed in a curing process may be reduced, thereby increasing the efficiency of the process.

In addition, the heat treatment apparatus 10 may include the plurality of temperature sensors 70 disposed in one side of the chamber 20. Accordingly, the heat treatment apparatus 10 may measure the temperature of the first internal space CS1 as the process space in real time.

Further, the heat treatment apparatus 10 may include the plurality of infrared temperature sensors 80 disposed on one side of the chamber 20. Accordingly, the heat treatment apparatus 10 may directly measure the temperature of an individual wafer in real time.

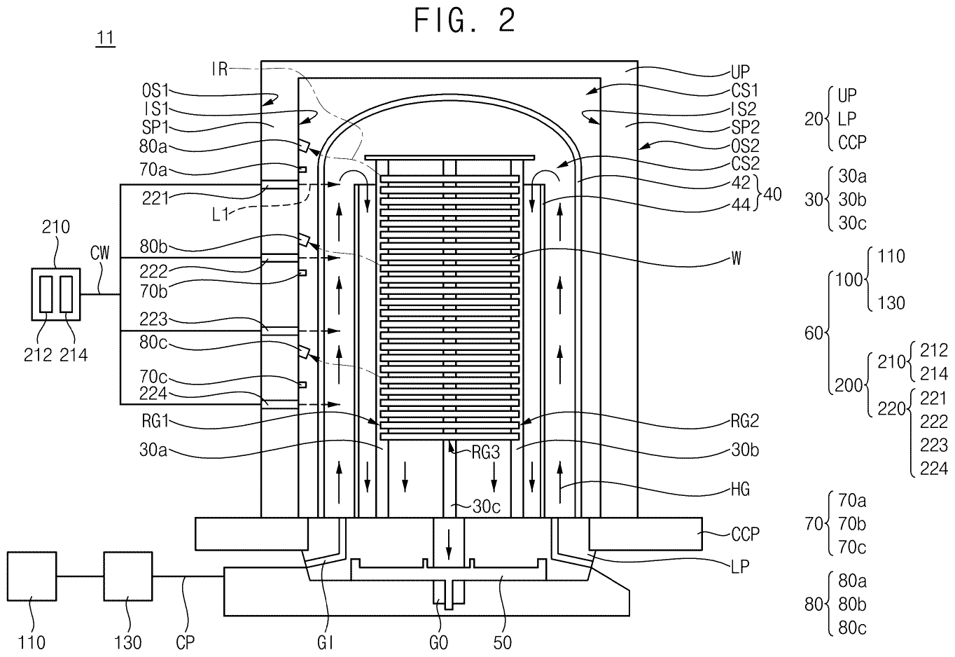

FIG. 2 is a cross-sectional view illustrating a heat treatment apparatus in accordance with example embodiments.

The heat treatment apparatus 11 illustrated in FIG. 2 is substantially the same as the heat treatment apparatus 10 described with reference to FIG. 1 except for a first heating device 100, and thus the same components are indicated by the same reference numerals, and repeated descriptions of the same components are omitted.

Referring to FIG. 2, a first heating device 100 of a heat treatment apparatus 11 may include a gas supply device 110 having at least one gas supply pipe GI, at least one gas discharge pipe GO, and connecting pipes CP, and an external heating device 130 for heating a heat transfer gas HG supplied from the gas supply device 110.

The at least one gas supply pipe GI may be disposed in a lower chamber LP and may be in fluid communication with a second internal space CS2 of a reaction tube 42. For example, the at least one gas supply pipe GI may be an inlet pipe for delivering the heat transfer gas HG to the second internal space CS2. In addition, the at least one gas discharge pipe GO may be disposed in the lower chamber LP and may be in fluid communication with the second internal space CS2 of the reaction tube 42. For example, the at least one gas discharge pipe may be an outlet pipe for delivering the heat transfer gas HG from the second internal space CS2 to the outside.

For example, the heat transfer gas may include nitrogen (N₂) gas or argon (Ar) gas. However, example embodiments are not limited thereto, and the type of the heat transfer gas may be varied.

The external heating device 130 may be disposed between the gas supply device 110 and the at least one gas supply pipe GI. For example, the external heating device 130 may heat the heat transfer gas HG supplied from the gas supply device 110, and then transfer the heat transfer gas HG having a relatively high temperature to the second internal space CS2 through the at least one gas supply pipe GI.

The connecting pipes CP may be disposed between the at least one gas supply pipe GI, the external heating device 130, and the gas supply device 110, and may be a plurality of pipes that are in fluid communication with the at least one gas supply pipe GI, the external heating device 130, and the gas supply device 110, respectively.

For example, the heat transfer gas HG may be injected into the second internal space CS2 of the reaction tube 42 through the gas supply device 110, the external heating device 130, the connecting pipes CP, and the at least one gas supply pipe GI. At this time, the heat transfer gas HG may be heated through the external heating device 130. Then, the injected heat transfer gas HG may pass between the reaction tube 42 and an inner tube 44, and then move toward the at least one gas discharge pipe GO through the inside of the inner tube 44. At this time, the heated heat transfer gas HG may heat a plurality of wafers W while moving inside the inner tube 44. Then, the heat transfer gas HG may be discharged to the outside through the at least one gas discharge pipe GO.

As mentioned above, the heat treatment apparatus 11 may include the first heating device 100 and a second heating device 200 for heating a plurality of wafers W. Accordingly, the multi-heating device 60 may perform a heat treatment process uniformly over the entire surface of the wafer while having a fast heating rate. Thus, a process time consumed in a curing process may be reduced, thereby increasing the efficiency of the process.

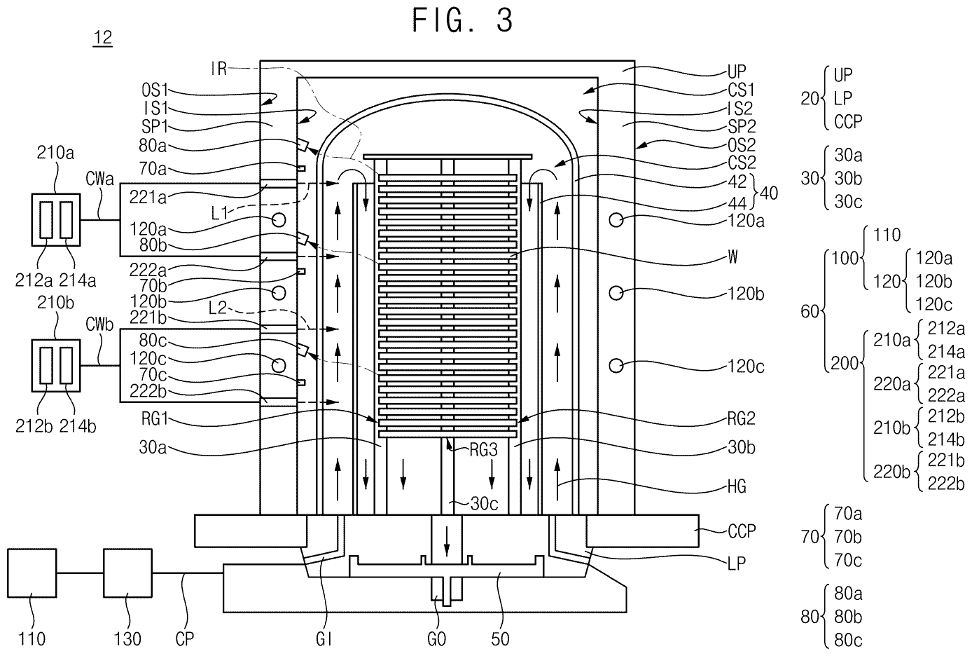

FIG. 3 is a cross-sectional view illustrating a heat treatment apparatus in accordance with example embodiments.

The heat treatment apparatus 12 illustrated in FIG. 3 is substantially the same as the heat treatment apparatus 10 described with reference to FIG. 1 except for a second heating device 200, and thus the same components are indicated by the same reference numerals, and a repeated description of the same components is omitted.

Referring to FIG. 3, a second heating device 200 of a heat treatment apparatus 12 may include a second microwave source 210a that includes a second microwave controller 212a and a second microwave amplifier 214a, and a second microwave transmission portion 220a that includes a plurality of second wave guides 221a, 222a. In addition, the second heating device 200 may include a third microwave source 210b that includes a third microwave controller 212b and a third microwave amplifier 214b, and a third microwave transmission portion 220b that includes a plurality of third wave guides 221b, 222b.

For example, the second microwave controller may be a portion for generating a first microwave L1 having a first variable frequency W1 that varies within a preset first frequency range. The first microwave amplifier may be a portion for amplifying the first microwave L1. In addition, the third microwave controller may be a portion for generating a second microwave L2 having a second variable frequency W2 that varies within a preset second frequency range. The second microwave amplifier may be a portion for amplifying the second microwave L2.

For example, the first variable frequency W1 and the second variable frequency W2 may be within a range of 4 GHz to 8 GHz (C band). For example, the first variable frequency W1 and the second variable frequency W2 may be within a range of 5.8 GHz to 6.8 GHz. However, example embodiments are not limited thereto, and the frequency ranges of the first variable frequency W1 and the second variable frequency W2 may be changed.

The first variable frequency W1 and the second variable frequency W2 may be at least partially different from each other. For example, the first variable frequency W1 may be within a range of 5.8 GHz to 6.0 GHz, and the second variable frequency W2 may be within a range of 6.0 GHz to 6.8 GHz.

The first variable frequency W1 and the second variable frequency W2 may vary differently within the same range. For example, the first variable frequency W1 may be periodically changed from 5.8 GHz to 6.8 GHz within a range of 5.8 GHz to 6.8 GHz. In addition, the second variable frequency W2 may be periodically changed from 6.8 GHz to 5.8 GHz within a range of 5.8 GHz to 6.8 GHz. For example, during a first time period T1, the first variable frequency W1 may be changed from 5.8 GHz to 6.8 GHz, and the second variable frequency W2 may be changed from 6.8 GHz to 5.8 GHz. Then, during a second time period T2, the first variable frequency W1 may be changed from 6.8 GHz to 5.8 GHz, and the second variable frequency W2 may be changed from 5.8 GHz to 6.8 GHz.

The plurality of second wave guides 221a, 222a may penetrate a first side portion SP1 of the chamber 20 to extend from a first outer surface OS1 of the first side portion SP1 to a first inner surface IS1. For example, the plurality of second wave guides 221a, 222a may include first and second guides 221a, 222a that are spaced apart from each other in a vertical direction. Each of the first guide 221a and the second guide 222a may be connected through connection guides CWa that are disposed between the first and second guides 221a, 222a and the second microwave source 210a.

For example, the first microwave L1 generated from the second microwave controller 212a may be amplified while passing through the second microwave amplifier 214a. Then, the amplified first microwave L1 may be irradiated into a first internal space CS1 as a process space through the connection guides CWa and the plurality of second wave guides 221a, 222a. Then, the first microwave L1 may pass through a reaction tube 42 and an inner tube 44 and reach a plurality of wafers W to heat the plurality of wafers W.

The plurality of third wave guides 221b, 222b may penetrate the first side portion SP1 of the chamber 20 to extend from the first outer side OS1 of the first side portion SP1 to the first inner side IS1. For example, the plurality of third wave guides 221b, 222b may include third and fourth guides 221b, 222b that are spaced apart from each other in the vertical direction. Each of the third guide 221b and the fourth guide 222b may be connected through connection guides CWb that are disposed between the third and fourth guides 221b, 222b and the third microwave source 210b.

For example, the second microwave L2 generated from the third microwave controller 212b may be amplified while passing through the third microwave amplifier 214b. Then, the amplified third microwave L3 may be irradiated into the first internal space CS1 as the process space through the connection guides CWb and the plurality of third wave guides 221b, 222b. Then, the second microwave L2 may pass through the reaction tube 42 and the inner tube 44 and reach the plurality of wafers W to heat the plurality of wafers W.

For example, the second heating device may be a multi-frequency microwave MFM device including a plurality of variable frequency microwave VFM devices. The second microwave source 210a and the second microwave transmission portion 220a may be a variable frequency microwave VFM device for irradiating a microwave whose frequency changes within a certain range. The third microwave source 210b and the third microwave transmission portion 220b may be a variable frequency microwave VFM device for irradiating a microwave whose frequency changes within a certain range.

Although several wave guides are illustrated in the figure, it will be understood that example embodiments are not limited thereto. Accordingly, the number and arrangement of wave guides may vary.

As mentioned above, the heat treatment apparatus 12 may include a first heating device 100 and the second heating device 200 for heating a plurality of wafers W.

Accordingly, the multi-heating device 60 may perform a heat treatment process uniformly over the entire surface of the wafer while having a fast heating rate. Thus, a process time consumed in a curing process may be reduced, thereby increasing the efficiency of the process.

In addition, the second heating device 200 may include a plurality of variable frequency microwave VFM devices.

Accordingly, the second heating device 200 may efficiently heat the plurality of wafers by utilizing microwaves L1, L2 having different frequencies.

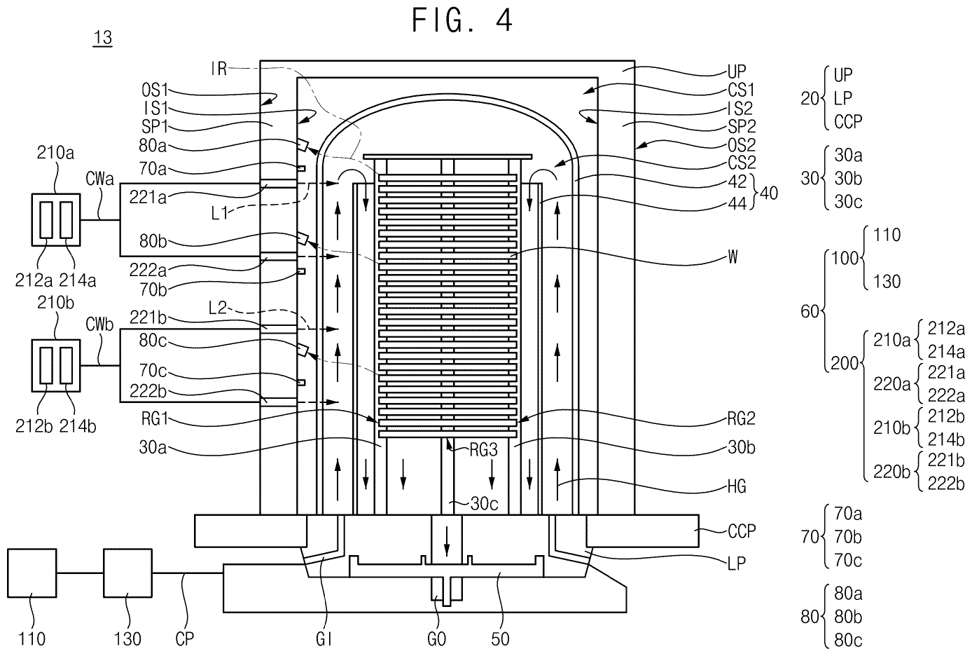

FIG. 4 is a cross-sectional view illustrating a heat treatment apparatus in accordance with example embodiments.

The heat treatment apparatus 13 illustrated in FIG. 4 is substantially the same as the heat treatment apparatus 12 described with reference to FIG. 3 except for a first heating device 100, and thus the same components are indicated by the same reference numerals, and repeated descriptions of the same components are omitted.

Referring to FIG. 4, a first heating device 100 of a heat treatment apparatus 13 may include a gas supply device 110 having at least one gas supply pipe GI, at least one gas discharge pipe GO, and connecting pipes CP, and an external heating device 130 for heating a heat transfer gas HG supplied from the gas supply device 110.

The first heating device 100 of the heat treatment apparatus 13 illustrated in FIG. 4 is substantially the same as the first heating device 100 of the heat treatment apparatus 11 described in FIG. 2, so that the same components are indicated by the same reference numerals, and a repeated description of the same components is omitted.

As described above, the heat treatment apparatus 13 may include the first heating device 100 and a second heating device 200 for heating a plurality of wafers W.

Accordingly, the multi-heating device 60 may perform a heat treatment process over the entire surface of the wafer while having a fast heating rate. Thus, a process time consumed in a curing process may be reduced, thereby increasing the efficiency of the process.

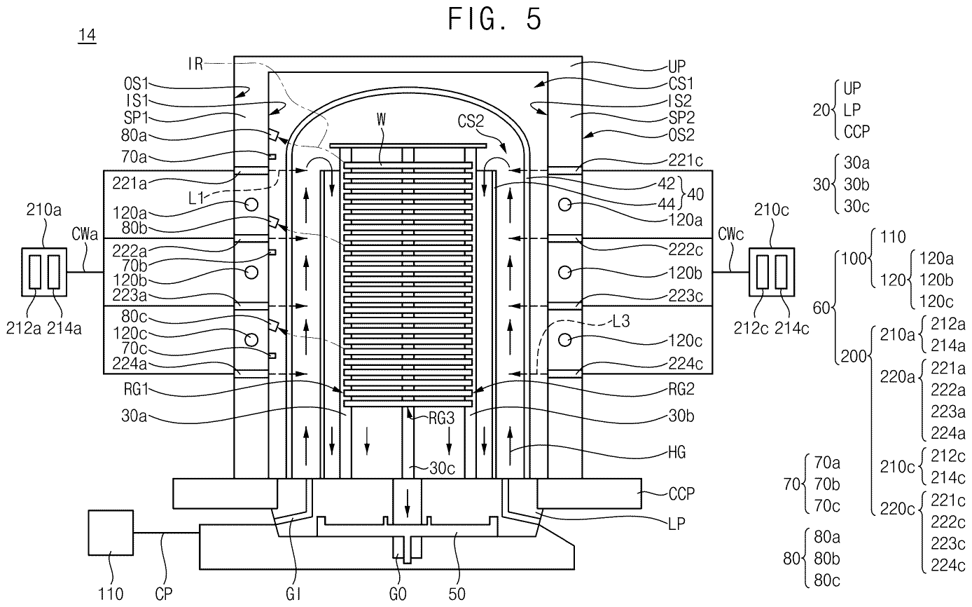

FIG. 5 is a cross-sectional view illustrating a heat treatment apparatus in accordance with example embodiments.

The heat treatment apparatus 14 illustrated in FIG. 5 is substantially the same as the heat treatment apparatus 10 described with reference to FIG. 1 except for a second heating device 200, and thus the same components are indicated by the same reference numerals, and a repeated description of the same components is omitted.

Referring to FIG. 5, a second heating device 200 of a heat treatment apparatus 14 may include a second microwave source 210a that includes a second microwave controller 212a and a second microwave amplifier 214a, and a second microwave transmission portion 220a that includes a plurality of second wave guides 221a, 222a, 223a, 224a. In addition, the second heating device 200 may include a fourth microwave source 210c that includes a fourth microwave controller 212c and a fourth microwave amplifier 214c, and a fourth microwave transmission portion 220c that includes a plurality of fourth wave guides 221c, 222c, 223c, 224c.

For example, the second microwave controller may be a portion for generating a first microwave L1 having a first variable frequency W1 that varies within a preset first frequency range. The first microwave amplifier may be a portion for amplifying the first microwave L1. In addition, the fourth microwave controller may be a portion for generating a third microwave L3 having a third variable frequency W3 that varies within a preset third frequency range. The fourth microwave amplifier may be a portion for amplifying the third microwave L3.

For example, the first variable frequency W1 and the third variable frequency W3 may be within a range of 4 GHz to 8 GHz (C band). For example, the first variable frequency W1 and the third variable frequency W3 may be within a range of 5.8 GHz to 6.8 GHz. However, example embodiments are not limited thereto, and the frequency ranges of the first variable frequency W1 and the third variable frequency W3 may be changed.

The first variable frequency W1 and the third variable frequency W3 may be at least partially different from each other. For example, the first variable frequency W1 may be within a range of 5.8 GHz to 6.0 GHz, and the third variable frequency W3 may be within a range of 6.0 GHz to 6.8 GHz.

The first variable frequency W1 and the third variable frequency W3 may vary differently within the same range. For example, the first variable frequency W1 may be periodically changed from 5.8 GHz to 6.8 GHz within a range of 5.8 GHz to 6.8 GHz. In addition, the third variable frequency W3 may be periodically changed from 6.8 GHz to 5.8 GHz within a range of 5.8 GHz to 6.8 GHz. For example, during a first time period T1, the first variable frequency W1 may be changed from 5.8 GHz to 6.8 GHz, and the third variable frequency W3 may be changed from 6.8 GHz to 5.8 GHz. Then, during a second time period T2, the first variable frequency W1 may be changed from 6.8 GHz to 5.8 GHz, and the third variable frequency W3 may be changed from 5.8 GHz to 6.8 GHz.

The plurality of second wave guides 221a, 222a, 223a, 224a may penetrate a first side portion SP1 of a chamber 20 to extend from a first outer surface OS1 of the first side portion SP1 of the chamber 20 to a first inner surface IS1. For example, the plurality of second wave guides 221a, 222a, 223a, 224a may include first to fourth guides 221a, 222a, 223a, 224a that are spaced apart from each other in a vertical direction. Each of the first to fourth guides 221a, 222a, 223a, 224a may be connected through connection guides CWa that are disposed between the first to fourth guides 221a, 222a, 223a, 224a and the second microwave source 210a.

For example, the first microwave L1 generated from the second microwave controller 212a may be amplified while passing through the second microwave amplifier 214a. Then, the amplified first microwave L1 may be irradiated into a first internal space CS1 as a process space through the connection guides CWa and the plurality of second wave guides 221a, 222a, 223a, 224a. Then, the first microwave L1 may pass through a reaction tube 42 and an inner tube 44 and reach a plurality of wafers W to heat the plurality of wafers W.

The plurality of fourth wave guides 221c, 222c, 223c, 224c may penetrate a second side portion SP2 of the chamber 20 to extend from a second outer surface OS2 of the second side portion SP2 to a second inner surface IS2. For example, the plurality of fourth wave guides 221c, 222c, 223c, 224c may include fifth to eighth guides 221c, 222c, 223c, 224c that are spaced apart from each other in the vertical direction. Each of the fifth to eighth guides 221c, 222c, 223c, 224c may be connected through connection guides CWc that are disposed between the fifth to eighth guides 221c, 222c, 223c, 224c and the fourth microwave source 210c.

For example, the third microwave L3 generated from the fourth microwave controller 212c may be amplified while passing through the fourth microwave amplifier 214c. Then, the amplified fourth microwave L4 may be irradiated into the first internal space CS1 as the process space through the connection guides CWc and the plurality of fourth wave guides 221c, 222c, 223c, 224c. Then, the third microwave L3 may pass through the reaction tube 42 and the inner tube 44 and reach the plurality of wafers W to heat the plurality of wafers W.

For example, the second heating device may be a multi-frequency microwave MFM device including a plurality of variable frequency microwave VFM devices. The second microwave source 210a and the second microwave transmission portion 220a may be a variable frequency microwave VFM device for irradiating a microwave whose frequency varies within a certain range. The fourth microwave source 210c and the fourth microwave transmission portion 220c may be a variable frequency microwave VFM device for irradiating a microwave whose frequency varies within a certain range.

Although several wave guides are illustrated in the figure, it will be understood that example embodiments are not limited thereto. Accordingly, the number and arrangement of wave guides may vary.

As mentioned above, the heat treatment apparatus 14 may include a first heating device 100 and the second heating device 200 for heating the plurality of wafers W.

Accordingly, the multi-heating device 60 may perform a heat treatment process uniformly over the entire surface of the wafer while having a fast heating rate. Accordingly, a process time consumed in a heat treatment process such as a curing process may be reduced, thereby increasing the efficiency of the process.

In addition, the second heating device 200 may include a plurality of variable frequency microwave VFM devices.

Accordingly, the second heating device 200 may efficiently heat the plurality of wafers by utilizing microwaves L1, L3 having different frequencies.

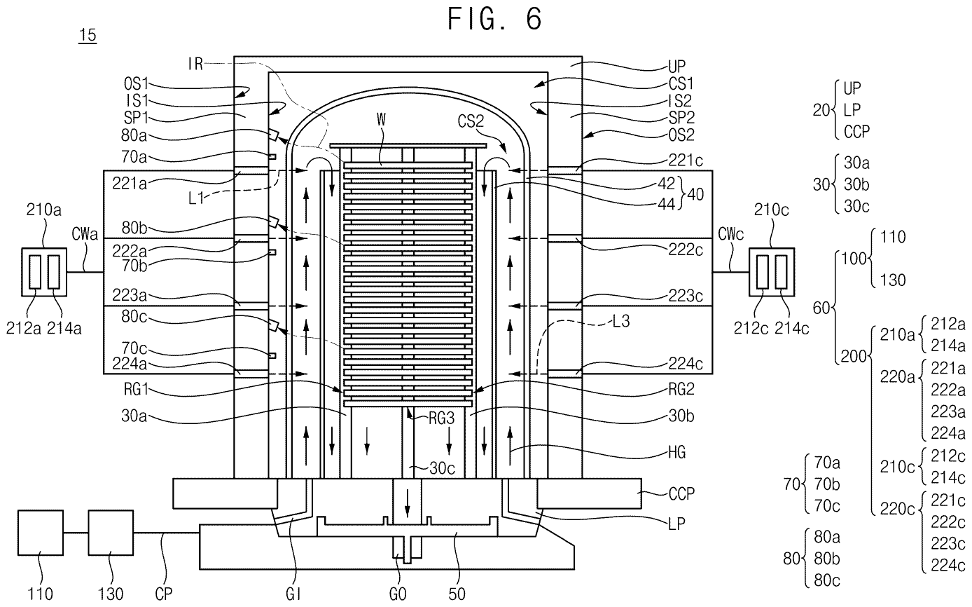

FIG. 6 is a cross-sectional view illustrating a heat treatment apparatus in accordance with example embodiments.

The heat treatment apparatus 15 illustrated in FIG. 6 is substantially the same as the heat treatment apparatus 14 described with reference to FIG. 5 except for a first heating device 100, and thus the same components are indicated by the same reference numerals, and repeated descriptions of the same components are omitted.

Referring to FIG. 6, s first heating device 100 of a heat treatment apparatus 15 may include a gas supply device 110 having at least one gas supply pipe GI, at least one gas discharge pipe GO, and connecting pipes CP, and an external heating device 130 for heating a heat transfer gas HG supplied from the gas supply device 110.

The first heating device 100 of the heat treatment apparatus 15 illustrated in FIG. 6 is substantially the same as the first heating device 100 of the heat treatment apparatus 11 described with reference to FIG. 2, so that the same components are indicated by the same reference numerals, and repeated descriptions of the same components are omitted.

As mentioned above, the heat treatment apparatus 15 may include the first heating device 100 and a second heating device 200 for heating a plurality of wafers W.

Accordingly, the multi-heating device 60 may perform a heat treatment process uniformly over the entire surface of the wafer while having a fast heating rate. Thus, a process time consumed in a curing process may be reduced, thereby increasing the efficiency of the process.

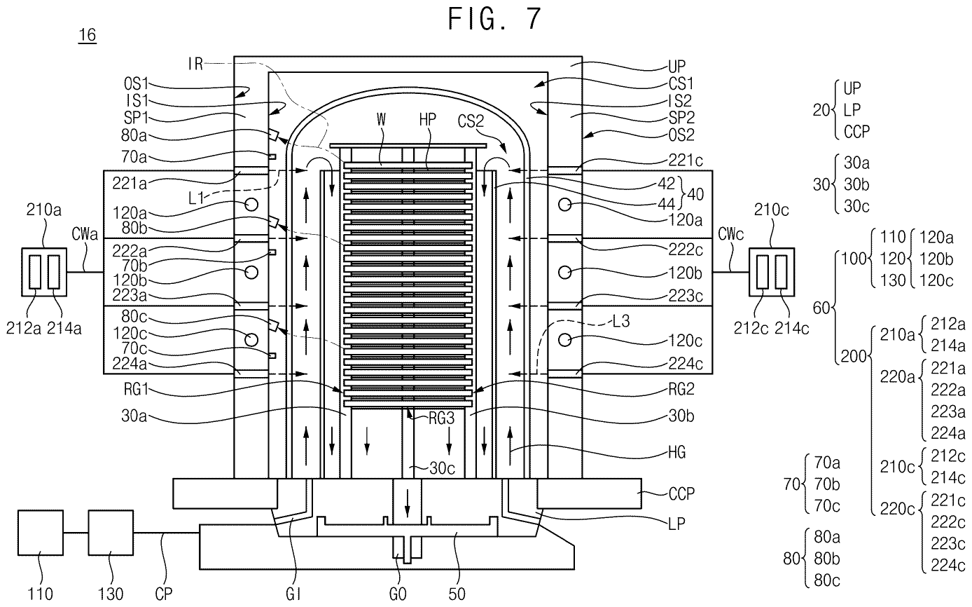

FIG. 7 is a cross-sectional view illustrating a heat treatment apparatus in accordance with example embodiments.

The heat treatment apparatus 16 illustrated in FIG. 7 is substantially the same as the heat treatment apparatus 15 described with reference to FIG. 6 except for a wafer boat 30, and thus the same components are indicated by the same reference numerals, and repeated descriptions of the same components are omitted.

Referring to FIG. 7, a wafer boat 30 of a heat treatment apparatus 16 may be provided in a first internal space CS1 of a chamber 20 and may include a plurality of supports 30a, 30b, 30c each having a plurality of receiving grooves. For example, the wafer boat may be a structure for fixedly support a plurality of wafers by inserting the plurality of wafers into the plurality of receiving grooves. The wafer boat may include a heat-resistant material that is capable of withstanding heat during a curing process. In addition, the wafer boat may include a transparent material to transmit light. For example, the wafer boat may include quartz.

For example, the wafer boat 30 may include a first support 30a, a second support 30b, and a third support 30c that are spaced apart from each other in a horizontal direction. The first support 30a may include a plurality of first receiving grooves RG1 that are spaced apart from each other in a vertical direction, the second support 30b may include a plurality of second receiving grooves RG2 that are spaced apart from each other in the vertical direction, and the third support 30c may include a plurality of third receiving grooves RG3 that are spaced apart from each other in the vertical direction.

The wafer boat 30 may include a plurality of heating plates HP that are disposed between the plurality of first to third receiving grooves RG1, RG2, RG3. For example, each of the heating plates may include annular heating wires for heating adjacent wafers.

Accordingly, the heat treatment apparatus 16 may heat the plurality of wafers W through a first heating device 100 and a second heating device. In addition, the heat treatment apparatus 16 may individually heat the plurality of wafers W through the plurality of heating plates HP.

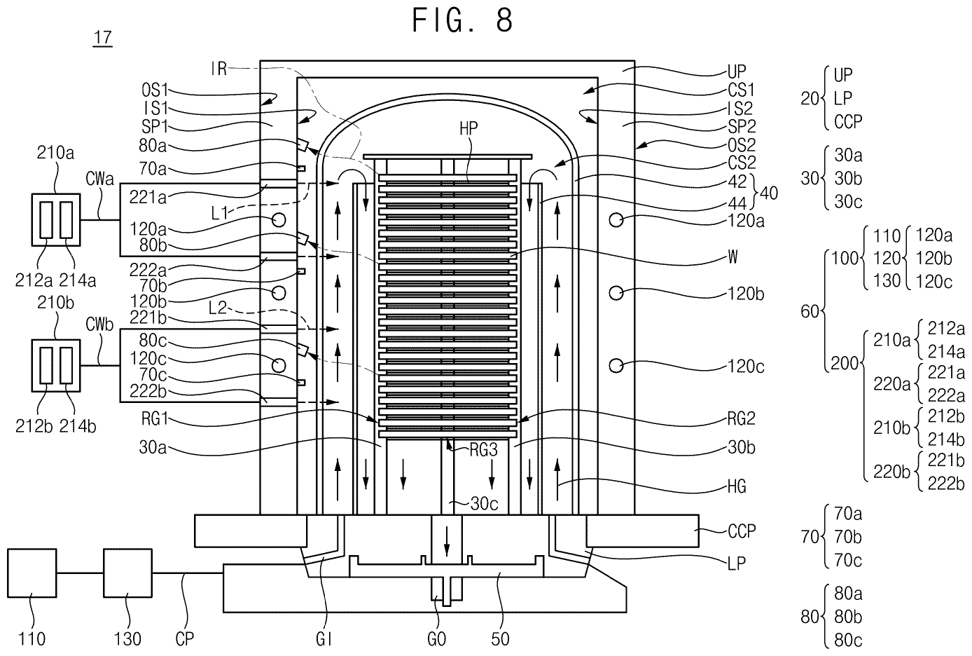

FIG. 8 is a cross-sectional view illustrating a heat treatment apparatus in accordance with example embodiments.

The heat treatment apparatus 17 illustrated in FIG. 8 is substantially the same as the heat treatment apparatus 13 described with respect to FIG. 4 except for a wafer boat 30, and thus the same components are indicated by the same reference numerals, and repeated descriptions of the same components are omitted.

Referring to FIG. 8, a wafer boat 30 of a heat treatment apparatus 17 may be disposed in a first internal space CS1 of a chamber 20, and may include a plurality of supports 30a, 30b, 30c each having a plurality of receiving grooves. In addition, the wafer boat 30 of the heat treatment apparatus 17 may include a plurality of heating plates HP each disposed between the plurality of receiving grooves.

The wafer boat 30 of the heat treatment apparatus 17 illustrated in FIG. 8 is substantially the same as the wafer boat 30 of the heat treatment apparatus 16 described with reference to FIG. 7, so that the same components are indicated by the same reference numerals, and a repeated description of the same components is omitted.

Accordingly, the heat treatment apparatus 17 may heat a plurality of wafers W through a first heating device 100 and a second heating device. In addition, the heat treatment apparatus 17 can individually heat the plurality of wafers W through the plurality of heating plates HP.

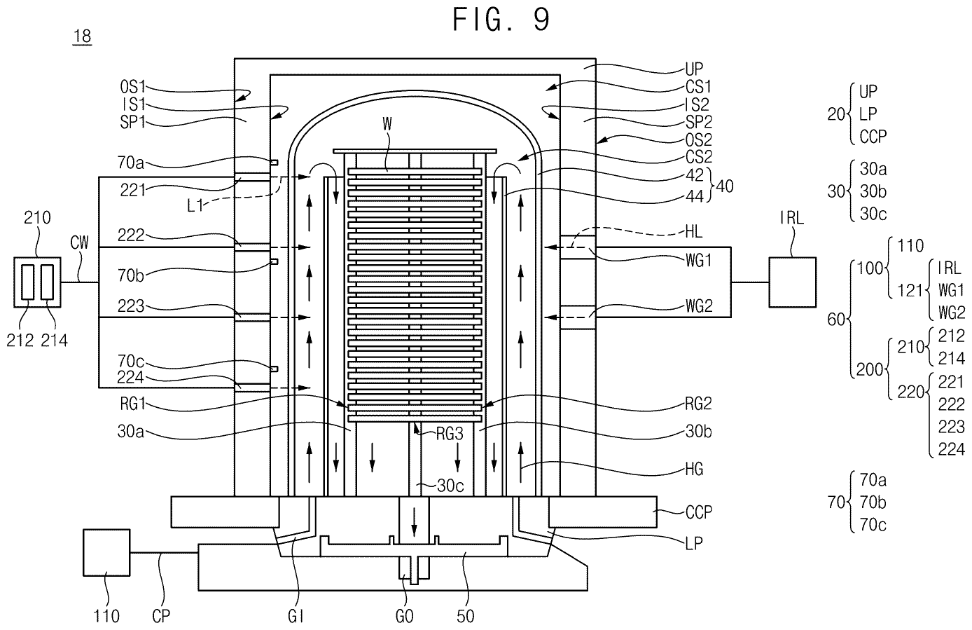

FIG. 9 is a cross-sectional view illustrating a heat treatment apparatus in accordance with example embodiments.

The heat treatment apparatus 18 illustrated in FIG. 9 is substantially the same as the heat treatment apparatus 10 described with reference to FIG. 1 except for a first heating device 100, and thus, the same components are indicated by the same reference numerals, and a repeated description of the same components is omitted.

Referring to FIG. 9, a first heating device 100 of a heat treatment apparatus 18 may include a gas supply device 110 for supplying a heat transfer gas HG and a gas heating device 121 having an infrared lamp IRL for heating the heat transfer gas HG.

The gas supply device 110 of the heat treatment apparatus 18 illustrated in FIG. 9 is substantially the same as the gas supply device 110 of the heat treatment apparatus 10 described with reference to FIG. 1, and thus the same components are indicated by the same reference numerals, and a repeated description of the same components is omitted.

The gas heating device 121 may include the infrared lamp IRL configured to emit infrared HL, and a plurality of wave guides WG1, WG2 for lamps provided in a second side portion SP2 of a chamber 20 and configured to transmit the infrared HL. For example, the plurality of wave guides WG1, WG2 for lamps may penetrate the second side portion SP2 to extend from a second outer side OS2 of the second side portion SP2 to a second inner side IS2 and may be spaced apart from each other in a vertical direction.

For example, the infrared HL of the infrared lamp IRL may reach a heat transfer gas HG through each of the plurality of wave guides WG1, WG2 for lamps, thereby heating the heat transfer gas HG. Accordingly, the first heating device 100 of the heat treatment apparatus 18 may heat the heat transfer gas HG by utilizing the infrared lamp IRL, to thereby achieve relatively uniform and rapid heat transfer during a curing process.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A heat treatment apparatus, comprising:
a wafer boat accommodating a plurality of wafers;
a reaction tube surrounding the wafer boat and defining a sealed first internal space;
a chamber surrounding the reaction tube and having a first side portion and a second side portion facing each other; and
a multi-heating device including a first heating device and a second heating device configured to heat the plurality of wafers,
wherein the first heating device includes a gas supply device configured to supply a heat transfer gas to the first internal space and a gas heating device configured to heat the heat transfer gas, and
wherein the second heating device includes a first microwave source configured to generate a first microwave having a first variable frequency that varies within a first frequency range and a first microwave transmission portion including at least one first wave guide that penetrates the first side portion of the chamber and configured to transmit the first microwave.

2. The heat treatment apparatus of claim 1, wherein the gas heating device of the first heating device comprises at least one infrared lamp for heating the heat transfer gas and at least one wave guide for lamp that penetrates the second side portion of the chamber.

3. The heat treatment apparatus of claim 1, wherein the gas heating device of the first heating device comprises at least one heater for heating the heat transfer gas, and the at least one heater is disposed in the first side portion and the second side portion of the chamber to surround the plurality of wafers.

4. The heat treatment apparatus of claim 1, wherein the gas heating device of the first heating device comprises an external heating device for heating the heat transfer gas, and the external heating device is disposed between the first internal space and the gas supply device.

5. The heat treatment apparatus of claim 1, wherein the second heating device further comprises a second microwave source configured to generate a second microwave having a second variable frequency that varies within a second frequency range, and a second microwave transmission portion including at least one second wave guide that penetrates the first side portion of the chamber and transmits the second microwave.

6. The heat treatment apparatus of claim 5, wherein the first frequency range of the first variable frequency is at least partially different from the second frequency range of the second variable frequency.

7. The heat treatment apparatus of claim 5, wherein the first frequency range of the first variable frequency is the same as the second frequency range of the second variable frequency, and the first variable frequency and the second variable frequency vary differently from each other.

8. The heat treatment apparatus of claim 1, wherein the second heating device further comprises a third microwave source configured to generate a third microwave having a third variable frequency that varies within a third frequency range, and a third microwave transmission portion including at least one third wave guide that penetrates the second side portion of the chamber and transmits the third microwave.

9. The heat treatment apparatus of claim 1, wherein the wafer boat further comprises a plurality of heating plates for heating the plurality of wafers, and the plurality of the heating plates are disposed between a plurality of receiving grooves for supporting the plurality of wafers, respectively.

10. The heat treatment apparatus of claim 1, further comprising:
at least one temperature sensor disposed on at least one of the first side portion or the second side portion of the chamber and configured to measure temperature of the first internal space inside the chamber; and
at least one infrared temperature sensor disposed on at least one of the first side portion or the second side portion of the chamber and configured to measure temperature of each of the plurality of wafers.

11. A heat treatment apparatus, comprising:
a wafer boat having receiving grooves for receiving a plurality of wafers, respectively;
a reaction tube surrounding the wafer boat and defining a sealed first internal space;
a chamber surrounding the reaction tube and having a first side portion and a second side portion facing each other;
a first heating device configured to heat the plurality of wafers, the first heating device including a gas supply device configured to supply a heat transfer gas to the first internal space and a gas heating device configured to heating the heat transfer gas; and
a second heating device including:
a first microwave source configured to generate a first microwave having a first variable frequency that varies within a first frequency range;
a first microwave transmission portion having at least one first wave guide that penetrates the first side portion of the chamber and transmits the first microwave;
a second microwave source configured to generate a second microwave having a second variable frequency that varies within a second frequency range; and
a second microwave transmission portion having at least one second wave guide that penetrates the second side portion of the chamber and configured to transmit the second microwave.

12. The heat treatment apparatus of claim 11, wherein the gas supply device of the first heating device comprises at least one gas supply pipe in fluid communication with the first internal space.

13. The heat treatment apparatus of claim 11, wherein the gas heating device of the first heating device comprises at least one heater for heating the heat transfer gas, and the at least one heater is disposed in the first side portion and the second side portion of the chamber to surround the plurality of wafers.

14. The heat treatment apparatus of claim 11, wherein the gas heating device of the first heating device comprises an external heating device for heating the heat transfer gas, and the external heating device is disposed between the first internal space and the gas supply device.

15. The heat treatment apparatus of claim 11, wherein the first frequency range of the first variable frequency is at least partially different from the second frequency range of the second variable frequency.

16. The heat treatment apparatus of claim 11, wherein the first frequency range of the first variable frequency is the same as the second frequency range of the second variable frequency, and the first variable frequency and the second variable frequency vary differently from each other.

17. The heat treatment apparatus of claim 11, wherein the second heating device further comprises a third microwave source configured to generate a third microwave having a third variable frequency that varies within a third frequency range, and a third microwave transmission portion including at least one third wave guide that penetrates the second side portion of the chamber and transmits the third microwave.

18. The heat treatment apparatus of claim 17, wherein the first frequency range of the first variable frequency is at least partially different from the third frequency range of the third variable frequency.

19. The heat treatment apparatus of claim 17, wherein the first frequency range of the first variable frequency is the same as the third frequency range of the third variable frequency, and the first variable frequency and the third variable frequency vary differently from each other.

20. A heat treatment apparatus, comprising:
a wafer boat having receiving grooves for receiving a plurality of wafers, respectively;
a reaction tube surrounding the wafer boat and defining a sealed first internal space;
a chamber surrounding the reaction tube and having a first side portion and a second side portion facing each other;
a first heating device configured to heat the plurality of wafers, the first heating device including:
a gas supply device having at least one gas supply pipe in fluid communication with the first internal space and configured to supply a heat transfer gas to the first internal space;
an external heating device disposed between the first internal space and the gas supply device and configured to heat the heat transfer gas; and
at least one heater disposed in the first side portion and the second side portion of the chamber to surround the plurality of wafers and configured to heat the chamber; and
a second heating device including a first microwave source configured to generate a first microwave having a first variable frequency that varies within a first frequency range and a first microwave transmission portion having at least one first wave guide that penetrates the first side portion of the chamber and configured to transmit the first microwave.
